(19) United States
(12) Patent Application Publication
(10) Pub. No.: US 2017/0160087 A1
(43) Pub. Date: Jun. 8, 2017

(54) ANGULAR VELOCITY SENSOR

(71) Applicant: Panasonic Intellectual Property Management Co., Ltd., Osaka (JP)

(72) Inventor: TAKAMI ISHIDA, Osaka (JP)

(73) Assignee: Panasonic Intellectual Property Management Co., Ltd., Osaka (JP)

(21) Appl. No.: 15/300,005

(22) PCT Filed: Jun. 3, 2015
(86) PCT No.: PCT/JP2015/002811

§ 371 Date: Sep. 28, 2016

(30) Foreign Application Priority Data
Jun. 27, 2014 (JP) 2014-132236

(51) Int. Cl. G01C 19/5607; H01L 41/187; H01L 41/332; H01L 41/113

(52) U.S. Cl. CPC G01C 19/5607; H01L 41/113; H01L 41/1876; H01L 41/332

(57) ABSTRACT

An angular velocity sensor includes a substrate, a lower electrode on the substrate, a piezoelectric body on the lower electrode, and an upper electrode on the piezoelectric body. The piezoelectric body includes a first portion and a second portion above the first portion. The first portion has a side surface connected to a lower surface of the piezoelectric body. The second portion has a side surface connected to an upper surface of the piezoelectric body. A supplementary angle of an angle formed between the upper surface and the side surface of the second portion of the piezoelectric body is smaller than an angle formed between the lower surface and the side surface of the first portion of the piezoelectric body. This angular velocity sensor can effectively prevent stress from concentrating to the piezoelectric body.

### TECHNICAL FIELD

The present invention relates to an angular velocity sensor including a thin piezoelectric film, typically employed in navigation systems.

### BACKGROUND ART

A conventional angular velocity sensor includes a lower electrode, piezoelectric body, and upper electrode stacked on a silicon substrate in this order. A step is provided in a side surface of the piezoelectric body.

PTL1 discloses a conventional angular velocity sensor similar to this angular velocity sensor.

### CITATION LIST

### Patent Literature

PTL1: Japanese Patent No. 3829861

PTL2: Japanese Patent Laid-Open Publication No. 2008-085291

PTL3: Japanese Patent Laid-Open Publication No. 2009-089006

PTL4: International Publication No. WO2006/134744

PTL5: Japanese Patent No. 5398315

### SUMMARY

An angular velocity sensor includes a substrate, a lower electrode on the substrate, a piezoelectric body on the lower electrode, and an upper electrode on the piezoelectric body. The piezoelectric body includes a first portion and a second portion above the first portion. The first portion has a side surface connected to a lower surface of the piezoelectric body. The second portion has a side surface connected to an upper surface of the piezoelectric body. A supplementary angle of an angle formed between the upper surface and the side surface of the second portion of the piezoelectric body is smaller than an angle formed between the lower surface and the side surface of the first portion of the piezoelectric body.

This angular velocity sensor can effectively prevent stress from concentrating to the piezoelectric body.

### BRIEF DESCRIPTION OF DRAWINGS

FIG. 1 is a plan view of an angular velocity sensor in accordance with an exemplary embodiment.

FIG. 2 is a sectional view taken along line II-II of the angular velocity sensor in FIG. 1.

FIG. 3A illustrates a method of manufacturing the angular velocity sensor in accordance with the embodiment.

FIG. 3B illustrates the method of manufacturing the angular velocity sensor in accordance with the embodiment.

FIG. 3C illustrates the method of manufacturing the angular velocity sensor in accordance with the embodiment.

FIG. 3D illustrates the method of manufacturing the angular velocity sensor in accordance with the exemplary embodiment.

FIG. 4 is a sectional view of another angular velocity sensor in accordance with the embodiment.

FIG. 5A is a sectional view of the angular velocity sensor in FIG. 4 for illustrating a method of manufacturing the angular velocity sensor.

FIG. 5B is a sectional view of the angular velocity sensor in FIG. 4 for illustrating the method of manufacturing the angular velocity sensor.

FIG. 5C is a sectional view of the angular velocity sensor in FIG. 4 for illustrating the method of manufacturing the angular velocity sensor.

FIG. 5D is a sectional view of the angular velocity sensor in FIG. 4 for illustrating the method of manufacturing the angular velocity sensor.

FIG. 6 is a sectional view of still another angular velocity sensor in accordance with the embodiment.

FIG. 7 is a sectional view of still another angular velocity sensor in accordance with the embodiment.

### DETAIL DESCRIPTION OF PREFERRED EMBODIMENT

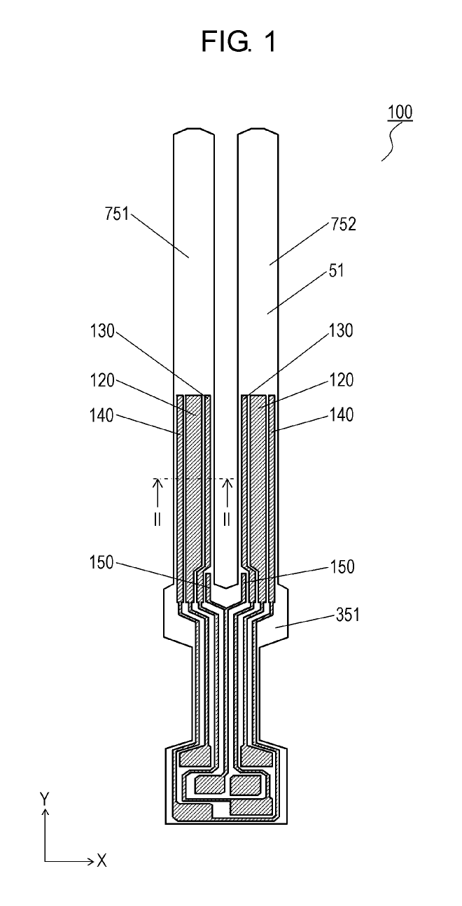

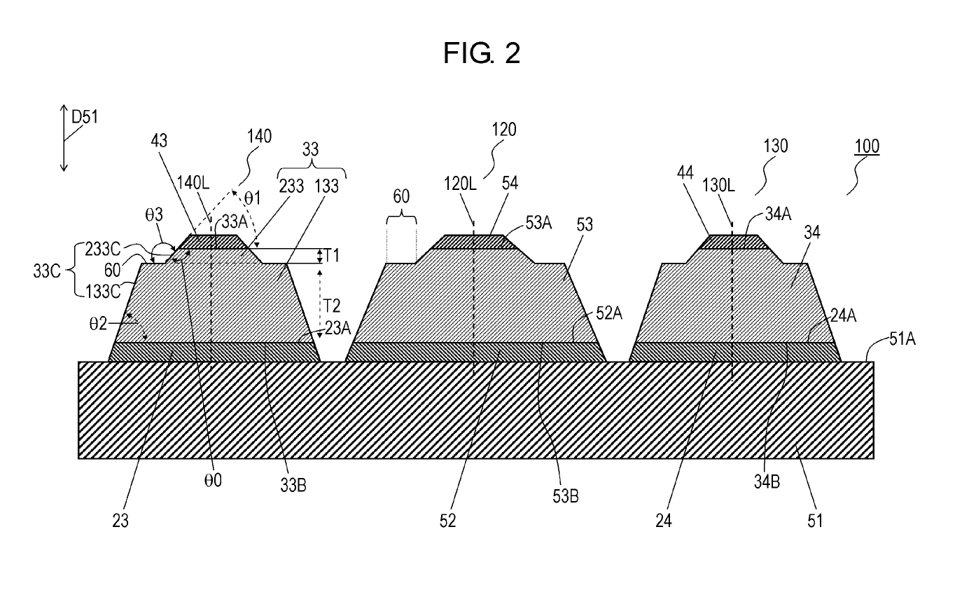

FIG. 1 is a plan view of angular velocity sensor 100 in accordance with an exemplary embodiment. FIG. 2 is a sectional view of the angular velocity sensor on line II-II shown in FIG. 1.

Substrate 51 is formed by processing a silicon, and has a tuning-fork shape including connecting part 351 and two arms 751 and 752 having respective one ends connected to connecting part 351. Arms 751 and 752 extend in parallel to each other. Detector part 120 and driver parts 130 and 140 are provided on upper surface 51A of substrate 51 at each of arms 751 and 752. Detector part 120 is positioned between driver parts 130 and 140. Each of driver parts 130 is positioned on respective one of inner sides of arms 751 and 752 parallel to each other while each of driver parts 140 is positioned on respective one of outer sides of arms 751 and 752 parallel to each other. Angular velocity sensor 100 is formed by processing substrate 51, detector part 120, and driver parts 130 and 140 to have a predetermined shape. An insulating film made insulation material, such as silicon oxide, is formed on a surface of substrate 51 to provide at least upper surface 51A with an insulating property.

Substrate 51 of angular velocity sensor 100 according to the embodiment has a tuning-fork shape, but may have another shape, such as an H-shape.

Driver parts 130 and 140 have shapes substantially identical to each other.

Detector part 120 includes lower electrode 52, piezoelectric body 53, and upper electrode 54 which are stacked on upper surface 51A of substrate 51 in this order.

Driver part 130 includes lower electrode 24, piezoelectric body 34, and upper electrode 44 which are stacked in this order.

Driver part 140 includes lower electrode 23, piezoelectric body 33, and upper electrode 43 which are stacked in this order.

In other words, angular velocity sensor 100 includes substrate 51, lower electrode 23 provided on upper surface 51A of substrate 51, piezoelectric body 33 having lower surface 33B provided on upper surface 23A of lower electrode 23, and upper electrode 43 provided on upper surface 33A of piezoelectric body 33. Lower electrode 23, piezoelectric body 33, and upper electrode 43 constitute driver part 140. Angular velocity sensor 100 further includes lower electrode 24 provided on upper surface 51A of substrate 51, piezoelectric body 34 having lower electrode 34B provided on upper surface 24A of lower electrode 24, and upper electrode 44 provided on upper surface 34A of piezoelectric body 34. Lower electrode 24, piezoelectric body 34, and upper electrode 44 constitute driver part 130. Angular velocity sensor 100 further includes lower electrode 52 provided on upper surface 51A of substrate 51, piezoelectric body 53 having lower surface 53B provided on upper surface 52A of lower electrode 52, and upper electrode 54 provided on upper surface 53A of piezoelectric body 53. Lower electrode 52, piezoelectric body 53, and upper electrode 54 constitute detector part 120.

Lower electrodes 23, 24, and 52 can be formed typically by deposition, sputtering, vapor film deposition, or plasma-assisted vapor film deposition of metal, such as platinum (Pt), alloy of platinum and titanium (Pt—Ti alloy), gold (Au), copper (Cu), nickel (Ni), or aluminum (Al); or oxide conductor, such as ruthenium oxide (RuO₂) or iridium oxide (IrO₂), on upper surface 51A of substrate 51.

A lead zirconate titanate (PZT) film is preferable as a material of piezoelectric bodies 33, 34, and 53 for easily forming a thin film with preferable crystal orientation. The material of piezoelectric bodies 33, 34, and 53 is not limited to lead zirconate titanate (PZT), but may be, for example, lead titanate (PT) film, lead zirconate (PZ) film, or lanthanum (La)-doped lead zirconate titanate (PLZT).

Upper electrodes 43, 44, and 54 may be made of the same material as lower electrodes 23, 24, and 52, and may be preferably made of metal since wire leads are mounted for electrical connection with external equipment. Upper electrodes 43, 44, and 54 may be made of an oxide, such as indium oxide (IrO₂), having a lattice constant close to that of piezoelectric bodies 33, 34, and 53.

Piezoelectric body 33 of driver part 140 has side surface 33C connected to upper surface 33A and lower surface 33B. Supplementary angle θ1 of angle θ0 formed between upper surface 33A of piezoelectric body 33 and side surface 33C of piezoelectric body 33 is preferably smaller than 45°.

Piezoelectric body 53 processed to have supplementary angle θ1 larger than 45° requires high power for dry etching. Dry etching at high power provides to side surface 33C of piezoelectric body 33 with large plasma damage, and deteriorates crystallinity of piezoelectric body 33 due to oxygen defect on side surface 33C of piezoelectric body 33. This deteriorates characteristics of piezoelectric body 33. Since poor crystallinity of side surface 33C of piezoelectric body 33 increases characteristic deterioration of piezoelectric body 33, supplementary angle θ1 is preferably smaller than 45°. Supplementary angle θ1 being excessively small increases the size of driver part 140, accordingly increasing the size of angular velocity sensor 100. Thus, supplementary angle θ1 is preferably larger than 20°. This configuration suppresses plasma damage to piezoelectric body 33. Detector part 120 and driver part 130 may have the same structure as driver part 140.

The conventional angular velocity sensor may produce a subtrench in the piezoelectric body at the dry etching. The subtrench is a dent (or a groove) produced in the piezoelectric body due to excessively etching a nonvolatile material (hard-to-etch material), such as a piezoelectric body, by dry etching. For example, this subtrench produced in the piezoelectric body causes stress to concentrate locally to the piezoelectric body during the drive (or detecting) operation of the piezoelectric body. This stress concentration tends to cause a crack in the piezoelectric body, thus degrading the reliability of the angular velocity sensor.

The subtrench will be described below. In dry etching, biased electric power is applied to substrate 51, and the surface of substrate 51 is first charged with electrons. Then, ion species (etching species) dissociated by plasma are attracted to the electrons, and reactive ion etching performed on the surface of substrate 51. If a corner at which lower surface 33B of piezoelectric body 33 meets the side surface of piezoelectric body 33 of driver part 140 (e.g., a portion of angle θ3 shown in FIG. 2) is close to 90°, an amount of electrons charged at the corner increases more than that on lower surface 33B and side surface 33C of piezoelectric body 33. Accordingly, ion species tend to be excessively attracted to the corner. This configuration etches the corner more than the other part. Consequently, angle θ3 close to 90° allows a dent to be produced about the etched position. This phenomenon is called subtrench. Prominent subtrench is produced in dry etching of a nonvolatile material (hard-to-etch material), such as a piezoelectric material, that requires high-ionic (high-power) etching. The subtrench causes stress to concentrate to the piezoelectric body during the drive (or detecting) operation of the piezoelectric body. This stress concentration may cause a crack in the piezoelectric body, hence degrading the reliability of the angular velocity sensor. In contrast, angular velocity sensor 100 according to the embodiment has supplementary angle θ1 equal to or smaller than 45°, and suppresses the subtrench. This configuration prevents a crack generated due to stress concentrating near the subtrench. Angle θ2 formed between lower surface 33B of piezoelectric body 33 and side surface 33C of piezoelectric body 33 is larger than both of 45° and supplementary angle θ1 suppresses influence of deteriorated piezoelectric characteristics of piezoelectric body 33 while providing angular velocity sensor 100 with a small size. Angle θ2 formed between lower surface 33B of piezoelectric body 33 and side surface 33C of piezoelectric body 33 of driver part 140 is smaller than 90°. This configuration prevents side surface 33C of piezoelectric body 33 and the side surface of lower electrode 23 from being perpendicular to upper surface 51A of substrate 51, and reduces local concentration of stress inside substrate 51.

The shape of piezoelectric body of driver part 140 will be detail below. Piezoelectric body 33 includes portion 133 having side surface 133C connected to lower surface 33B, and portion 233 having side surface 233C connected to upper surface 33A and positioned above the upper surface of portion 133. In accordance with the embodiment, portion 233 of piezoelectric body 33 is located on portion 133. In angular velocity sensor 100 in accordance with the embodiment, portion 233 of piezoelectric body 33 is positioned on the upper surface of portion 133 and connected to portion 133. Side surface 33C of the piezoelectric body includes side surfaces 133C and 233C and flat portion 60 which is connected to side surfaces 133C and 233C between side surfaces 133C and 233C.

An angle formed between side surface 233C in side surface 33C of piezoelectric body 33 and upper surface 33A of piezoelectric body 33 is angle θ0. An angle formed between side surface 133C in side surface 33C of piezoelectric body 33 and lower surface 33B of piezoelectric body 33 in driver part 140 is angle θ2. Thickness T1 of portion 233 having side surface 233C in direction D51 perpendicular to upper surface 51A of substrate 51 is preferably smaller than thickness T2 of portion 133 having side surface 133C in direction D51. This configuration provides angular velocity sensor 100 with a small size while suppressing deterioration of characteristics of piezoelectric body 33 of driver part 140.

Flat portion 60 of side surface 33C of piezoelectric body 33 is parallel to upper surface 51A of substrate 51. The width of flat portion 60 may range for example, from 1 to 2 μm. This configuration positions side surface 133C of portion 133 of piezoelectric body 33 away from upper electrode 43 of driver part 140. Since angle θ2 is large at side surface 133C of portion 133 of piezoelectric body 33, the piezoelectric characteristic greatly deteriorates typically by plasma processing. Side surface 133C of portion 133 of piezoelectric body 33 is located away at a position not contributing to detection of angular velocity, consequently improving the detection accuracy.

Driver part 130 and detector part 120 have the same structure as driver part 130. Each of piezoelectric bodies 33 and 34 of driver parts 130 and 140 and piezoelectric body 53 of detector part 120 is preferably symmetrical with respect to a line. For example, in FIG. 2, piezoelectric body 33 of driver part 140 is symmetrical with respect to line 140L, piezoelectric body 34 of driver part 130 is symmetrical with respect to line 130L, and piezoelectric body 53 of detector part 120 is symmetrical with respect to line 120L. This configuration improves symmetric property of angular velocity sensor 100, and improves e sensor accuracy.

Preferable relationship between angle θ0 (supplementary angle θ1) and angle θ2 or relationship between thicknesses T1 and T2, and the structure of flat portion 60 of piezoelectric body 33 of driver part 40 are also applicable to piezoelectric body 34 of driver part 140 and piezoelectric body 53 of detector part 120.

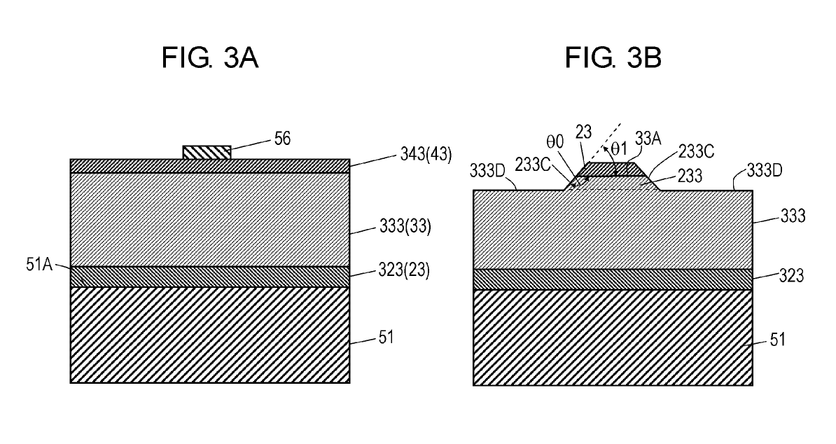

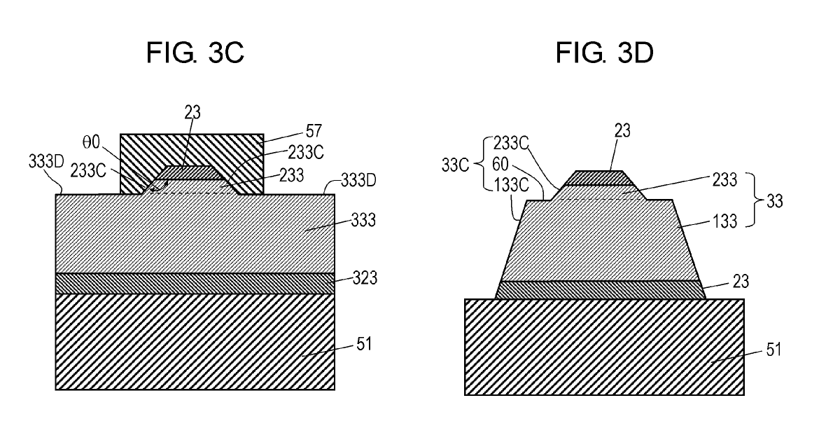

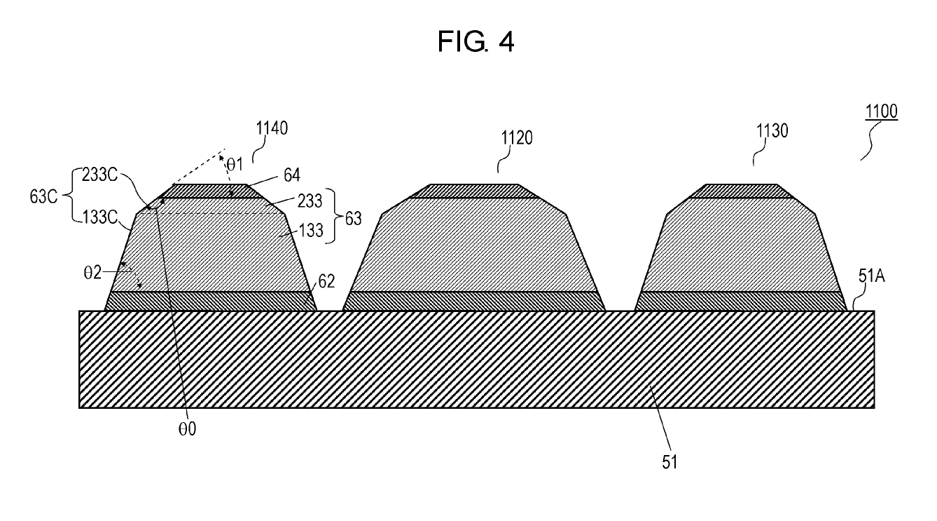

A method of manufacturing angular velocity sensor 100 will be described below. FIGS. 3A to 3D are enlarged sectional views of driver part 140 for illustrating the method of manufacturing angular velocity sensor 100 shown in FIGS. 1 and 2. Driver part 140 and detector part 120 can be formed simultaneously to driver part 140 by the same manufacturing method.

First, as shown in FIG. 3A, electrode layer 323 to become lower electrode 23 is formed on upper surface 51A of substrate 51. Then, piezoelectric layer 333 to become piezoelectric body 33 is formed on the upper surface of electrode layer 323. Electrode layer 343 to become upper electrode 43 is formed on the upper surface of piezoelectric layer 333. After thus stacking electrode layer 323, piezoelectric layer 333, and electrode layer 343 on upper surface 51A of substrate 51 in this order, a resist material is applied and exposed to form resist 56 with a predetermined shape on the upper surface of electrode layer 343.

Then, as shown in FIG. 3B, electrode layer 323 and piezoelectric layer 333 are dry-etched simultaneously to etch piezoelectric layer 333 to a middle before reaching the lower surface of piezoelectric layer 333. The etching stops when portion 233 of piezoelectric body 33 is formed. This configuration can form upper electrode 43 and portion 233 of piezoelectric body 33. New upper surface 333D of piezoelectric layer 333 connected to side surface 233C of portion 233 of piezoelectric body 33 is formed. Piezoelectric layer 333 may not be etched, and only electrode layer 343 may be etched to form only upper electrode 43.

Then, as shown in FIG. 3C, the resist material is applied and exposed again to form resist 57 with a predetermined shape covering upper electrode 43 on upper surface 333D of piezoelectric layer 333. Resist 57 covers upper electrode 43 and side surface 233C of portion 233 of piezoelectric body 33, and covers a part of upper surface 333D of piezoelectric layer 333.

Then, as shown in FIG. 3D, piezoelectric layer 333 and electrode layer 323 are dry-etched to form remaining portion 133 of piezoelectric body 33 and lower electrode 23.

The dry-etching of processes shown in FIG. 3A and FIG. 3C provides any supplementary angle θ1 of angle θ0 between upper surface 33A of piezoelectric body 33 and side surface 133C of portion 133 of piezoelectric body 33 and any angle θ2 between lower surface 33B of piezoelectric body 33 and side surface 133C of portion 133 of piezoelectric body 33 by, for example, controlling the etching power.

Piezoelectric layer 333 to become piezoelectric body 33 etched plural times prevents inability to perform the etching work during etching of piezoelectric layer 333 due to the resist being entirely etched and disappeared.

By repeating the processes shown in FIG. 3A and FIG. 3C, side surface 33C may be formed in multiple steps of three steps or more.

FIG. 4 is a sectional view of another angular velocity sensor 1100 in accordance with the embodiment. In FIG. 4, components identical to those of angular velocity sensor 100 shown in FIG. 2 are denoted by the same reference numerals. Angular velocity sensor 1100 includes driver parts 1130 and 1140 and detector part 1120 provided on upper surface 51A of substrate 51, instead of driver parts 130 and 140 and detector part 120 of angular velocity sensor 100 shown in FIG. 2. Driver part 1140 includes lower electrode 62 provided on upper surface 51A of substrate 51, piezoelectric body 63 provided on an upper surface of lower electrode 62, and upper electrode 64 provided on an upper surface of piezoelectric body 63, instead of lower electrode 23, piezoelectric body 33, and upper electrode 43 of driver part 140 shown in FIG. 2.

In angular velocity sensor 100 shown in FIG. 2, side surface 33C of piezoelectric body 63 of driver part 140 has flat portion 60 which is connected to side surfaces 133C and 233C between side surfaces 133C and 233C of portions 133 and 233 of piezoelectric body 33 and which is parallel to upper surface 51A of substrate 51. In driver part 1140 of angular velocity sensor 1100 shown in FIG. 4, side surface 63C of piezoelectric body 63 does not have flat portion 60, but has side surfaces 133C and 233C of portions 133 and 233 connected to each other. Side surfaces 133C and 233C are connected to each other. Driver part 1130 and detector part 1120 have the same structure as driver part 1140.

This configuration can suppress generation of a subtrench, and can improve the reliability of angular velocity sensor 1100. Further, since not having flat portion 60, detector part 120 and driver parts 130 and 140 can have a small size and provides angular velocity sensor 1100 with a small size.

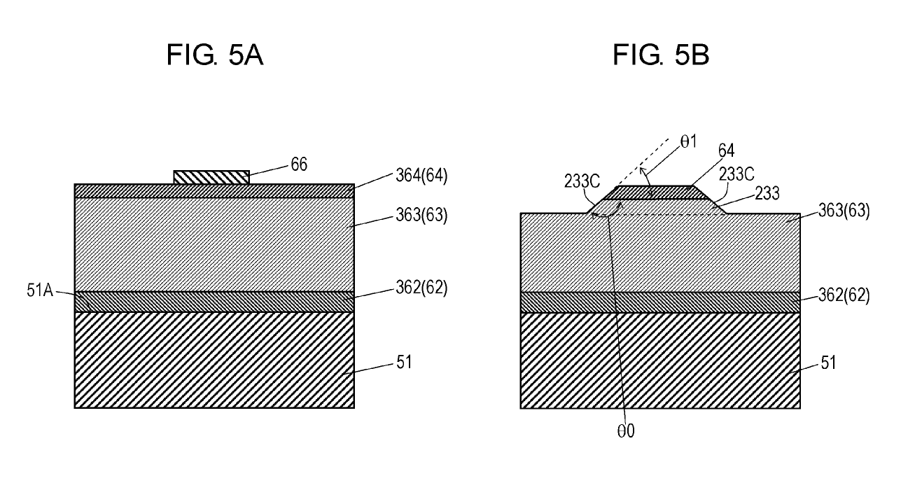

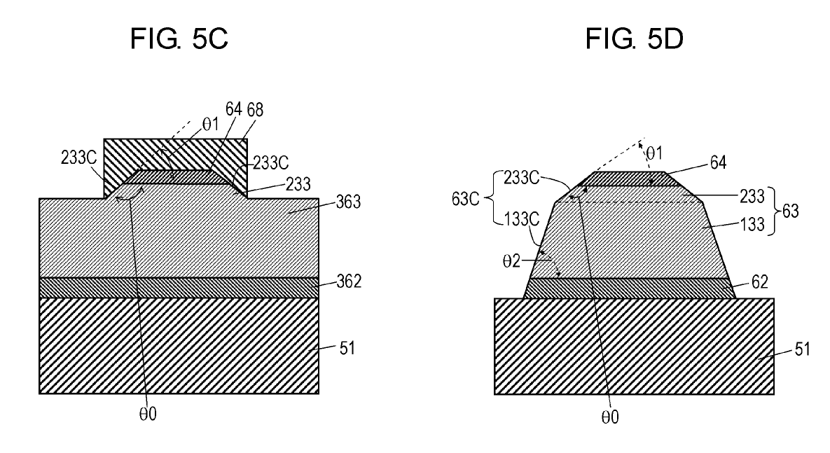

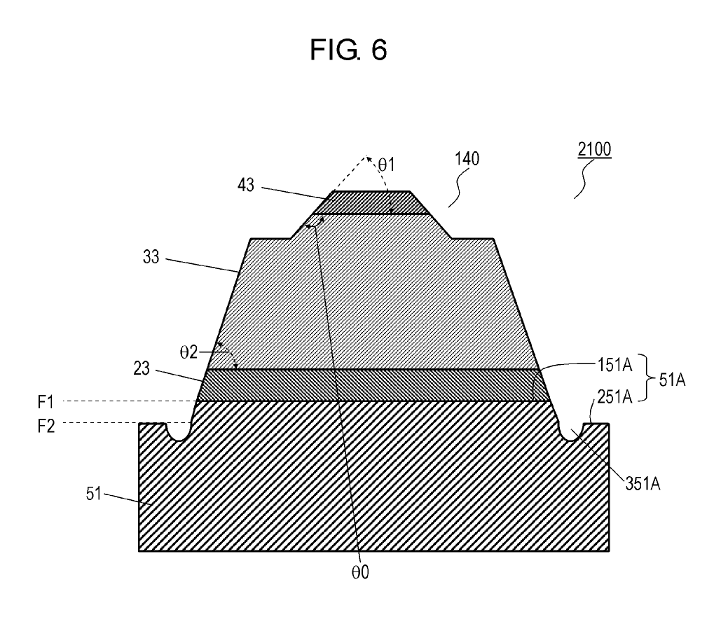

FIGS. 5A to 5D are enlarged sectional views of driver part 1140 for illustrating a method of manufacturing angular velocity sensor 1100 shown in FIG. 4. In FIGS. 5A to 5D, components identical to those of angular velocity sensor 100 shown in FIGS. 3A to 3D are denoted by the same reference numerals.

First, as shown in FIG. 5A, electrode layer 362 to become lower electrode 62 is formed on upper surface 51A of substrate 51. Piezoelectric layer 363 to become piezoelectric body 63 is formed on an upper surface of electrode layer 362. Electrode layer 364 to become upper electrode 64 is formed on an upper surface of piezoelectric layer 363, similarly to the process shown in FIG. 3A. Electrode layer 362, piezoelectric layer 363, and electrode layer 364 are thus stacked on upper surface 51A of substrate 51 in this order. Then, a resist material is applied and exposed to form resist 66 with a predetermined shape on the upper surface of electrode layer 364.

Then, as shown in FIG. 5B, electrode layer 364 and piezoelectric layer 363 are simultaneously dry-etched until piezoelectric layer 363 is etched to a middle. This forms upper electrode 64 and portion 233 of piezoelectric layer 63 having side surface 233C. Only electrode layer 364 may be etched without etching piezoelectric layer 363.

Then, as shown in FIG. 5C, a resist material is applied to cover upper electrode 64 and side surface 233C of portion 233 of piezoelectric layer 363 and exposed to form resist 68 with a predetermined shape.

Then, as shown in FIG. 5D, piezoelectric layer 363 and electrode layer 362 are dry-etched to form portion 133 of piezoelectric layer 63 and lower electrode 62.

Side surface 233C of portion 233 of piezoelectric body 63 constitutes a tapered portion. As shown in FIG. 5B and FIG. 5C, the thickness of resist 68 is larger than the thickness of resist 66, and the width of resist 68 is determined to conform to the lower end of the tapered portion (side surface 233C). This configuration allows piezoelectric body 63 to be processed without forming the flat portion on side surface 63C of piezoelectric body 63.

FIG. 6 is a sectional view of still another angular velocity sensor 2100 in accordance with the embodiment. In FIG. 6, components identical to those of angular velocity sensor 100 shown in FIG. 2 are denoted by the same reference numerals. In angular velocity sensor 100 shown in FIG. 2, upper surface 51A of substrate 51 is flat. In angular velocity sensor 2100 shown in FIG. 6, upper surface 51A of substrate 51 includes portion 151A (a surface along line F1 shown in FIG. 6) where lower electrode 23 is provided and portion 251A (a surface along line F2 shown in FIG. 6) where lower electrode 23 is not provided. Portion 151A of upper surface 51A of substrate 51 is located above portion 251A. Groove 351A is formed in upper surface 51A of substrate 51 between portions 151A and 251A.

This configuration can provide angular velocity sensor 2100 with a small size. Groove 351A constituting a subtrench formed in substrate 51 having a stable mechanical strength can prevents a crack produced due to stress concentration during the drive or detecting operation of angular velocity sensor 2100, accordingly improving the reliability of angular velocity sensor 2100.

In angular velocity sensor 2100, portions of upper surface 51A of substrate 51 where driver part 130 and detector part 120 are formed have the same structure.

In angular velocity sensor 2100, angle θ2 can be 90°.

An operation of angular velocity sensor 100 shown in FIG. 1 and FIG. 2 will be described below.

First, a voltage signal is applied to driver parts 130 and 140 from an external circuit to cause driver parts 130 and 140 to expand and contract. When driver part 140 expands, driver part 130 contracts to cause two arms 751 and 752 of substrate 51 having the shape of tuning fork to vibrate in a direction of an X-axis shown in FIG. 1.

When an angular velocity is applied to angular velocity sensor 100 while arms 751 and 752 are controlled to vibrate in directions along the X-axis, arms 751 and 752 vibrate in front-back directions opposite to each other in a plan view of FIG. 1 due to a Coriolis force. Detector part 120 detects amplitude of the vibration of arms 751 and 752 in the front-back directions. The external circuit outputs a value of the angular velocity based on the amount of a signal from detector part 120.

As shown in FIG. 1, monitor part 150 is preferably provided on substrate 51. Similarly to detector part 120 and driver parts 130 and 140, monitor part 150 includes a lower electrode provided on substrate 51, a piezoelectric body provided on the lower electrode, and an upper electrode provided on the piezoelectric body. A voltage signal is applied to driver parts 130 and 140 from the external circuit to cause arms 751 and 752 of substrate 51 to vibrate in the directions along the X-axis shown in FIG. 1. While arms 751 and 752 of substrate 51 vibrate in the directions along the X-axis, the piezoelectric body of monitor part 150 detects amplitude of the vibration of arms 751 and 752 of substrate 51. The amount of signal applied to driver parts 130 and 140 is controlled by comparing the detected amplitude pf the vibration with a reference value. This operation can control the amplitude of the vibration of arms 751 and 752 in the left and right directions of arms 751 and 752 to cause the amplitude to be constant. Monitor part 150 can be manufactured by the same method as driver part 140.

In all driver parts 130 and 140, detector part 120, and monitor part 150, supplementary angle θ1 of angle θ0 formed between the lower surface of the piezoelectric body and the side surface of the piezoelectric body do not necessarily be smaller than angle θ2 formed between the upper surface of the piezoelectric body and the side surface of the piezoelectric body. Supplementary angle θ1 of one or two of driver part 130, driver part 140, detector part 120, and monitor part 150 may be smaller than angle θ2.

In angular velocity sensor 100 in accordance with the embodiment, a silicon single crystal substrate is used as substrate 51. The silicon single crystal substrate can be easily processed, and has a smooth surface to have a high flatness easily. Therefore, the monocrystalline substrate is preferable in view of easy film formation and easy patterning of the lower electrode, the piezoelectric body, and the upper electrode. However, the material of the substrate is not limited to this material. For example, single crystal substrates such as a crystal and magnesium oxide single crystal substrates, amorphous substrates, such as a glass substrate and a quartz substrate, and ceramic substrates, such as of alumina and zirconium, may also be used. In the case that a glass substrate is used, sand blasting may be applied to form the tuning-fork shape.

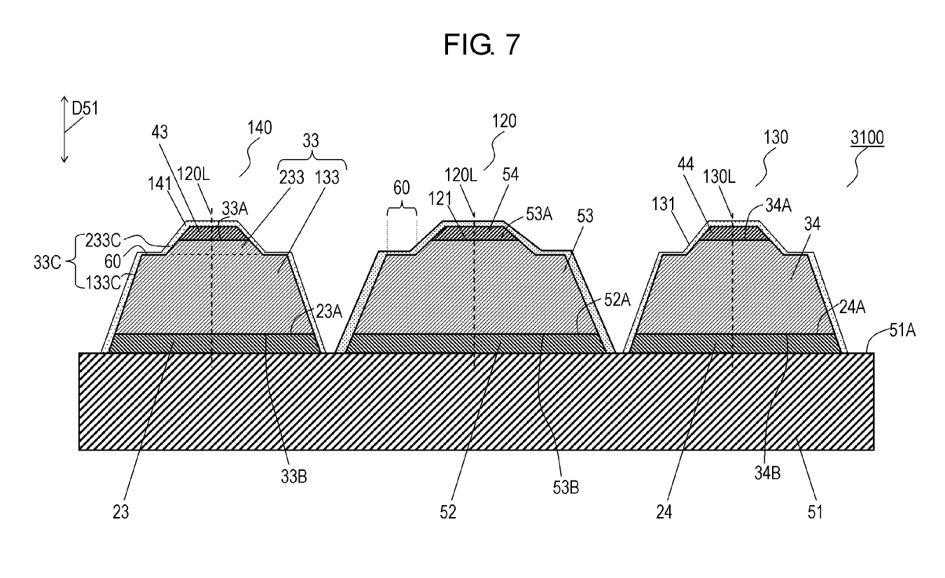

FIG. 7 is a sectional view of still another angular velocity sensor 3100 in accordance with the embodiment. In FIG. 7, components identical to those of angular velocity sensor 100 shown in FIG. 2 are denoted by the same reference numerals. Angular velocity sensor 3100 further includes insulating protective films 121, 131, and 141 covering the upper surfaces of the upper electrodes and the side surfaces of the piezoelectric bodies of detector part 120 and driver parts 130 and 140.

Portions that need to be protected by securely covered with protective films 121, 131, and 141 and inter-layer insulating layer are the side surface of the piezoelectric body and a boundary surface between the upper electrode and the piezoelectric body which largely influence the piezoelectric characteristics. In order to form a protective film with secure coverage without fail, with strong adhesion, and with a uniform film thickness on these portions, supplementary angle θ1 is preferably smaller than 45°. Protective films 121, 131, and 141 may be made of, e.g. aluminum oxide, silicon oxide, or silicon nitride.

In the embodiment, terms, such as “upper electrode”, “lower electrode”, “upper surface”, “lower surface”, and “above”, indicating directions indicate relative directions depending only on relative positional relation of components, such as the piezoelectric body, of the angular velocity sensor, and do not indicate absolute directions, such as a vertical direction.

### INDUSTRIAL APPLICABILITY

An angular velocity sensor according to the present invention has suppresses plasma damage to a piezoelectric body and suppresses stress concentration on the piezoelectric body to have high reliability, accordingly being applicable to an angular velocity sensor for vehicles.

### REFERENCE MARKS IN THE DRAWINGS

23, 24 lower electrode
33, 34 piezoelectric body
43, 44 upper electrode
51 substrate
52, 62 lower electrode
53, 63 piezoelectric body
54, 64 upper electrode
60 flat portion
100, 1100, 2100, 3100 angular velocity sensor
120 detector part
130 driver part
133 portion of piezoelectric body 33 (first portion)
233 portion of piezoelectric body 33 (second portion)
140 driver part
θ0 angle (first angle)
θ1 supplementary angle
θ2 angle (second angle)

1. An angular velocity sensor comprising:
a substrate;
a lower electrode provided on an upper surface of the substrate;
a piezoelectric body having a lower surface provided on an upper surface of the lower electrode; and
an upper electrode provided on an upper surface of the piezoelectric body,
wherein the piezoelectric body includes a first portion and a second portion provided above the first portion, the first portion of the piezoelectric body having a side surface connected to the lower surface of the piezoelectric body, the second portion of the piezoelectric body having a side surface connected to the upper surface of the piezoelectric body, and
wherein a supplementary angle of a first angle formed between the upper surface of the piezoelectric body and the side surface of the second portion of the piezoelectric body is smaller than a second angle formed between the lower surface of the piezoelectric body and the side surface of the first portion of the piezoelectric body.

2. The angular velocity sensor of claim 1, wherein the supplementary angle is smaller than 45°.

3. The angular velocity sensor of claim 2, wherein the supplementary angle is larger than 20°.

4. The angular velocity sensor of claim 1, wherein the second angle is smaller than 90° and larger than 45°.

5. The angular velocity sensor of claim 1, wherein a thickness of the first portion of the piezoelectric body in a direction perpendicular to the upper surface of the substrate is larger than a thickness of the second portion of the piezoelectric body in the direction.

6. The angular velocity sensor of claim 1, wherein the upper surface of the substrate has a first portion and a second portion provided above the first portion of the upper surfaced, the first portion of the substrate not contacting the lower electrode, the second portion of the substrate contacting the lower electrode.

7. The angular velocity sensor of claim 1, wherein the piezoelectric body contains lead titanate zirconate.

8. The angular velocity sensor of claim 1,
wherein the piezoelectric body has a side surface connected to the upper surface of the piezoelectric body and the lower surface of the piezoelectric body, and
wherein the side surface of the piezoelectric body does not have a flat portion parallel to the upper surface of the substrate.

9. The angular velocity sensor of claim 8, wherein the side surface of the first portion of the piezoelectric body is directly connected to the side surface of the second portion of the piezoelectric body.

10. The angular velocity sensor of claim 1,
wherein the piezoelectric body has a side surface connected to the upper surface of the piezoelectric body and the lower surface of the piezoelectric body, and
wherein the side surface of the piezoelectric body has a flat portion parallel to the substrate.

11. The angular velocity sensor of claim 10, wherein the flat portion of the side surface of the piezoelectric body is directly connected to the side surface of the first portion of the piezoelectric body and the side surface of the second portion of the piezoelectric body.

12. The angular velocity sensor of claim 11, further comprising a protective film covering an upper surface of the upper electrode.

13. The angular velocity sensor of claim 1, further comprising a protective film covering the piezoelectric body,
wherein the piezoelectric body has a side surface connected to the upper surface of the piezoelectric body and the lower surface of the piezoelectric body, and
wherein the protective film covers at least the side surface of the piezoelectric body.

14. The angular velocity sensor of claim 13, wherein the protective film covers the side surface of the piezoelectric body and an upper surface of the upper electrode.

15. The angular velocity sensor of claim 13, wherein the side surface of the piezoelectric body does not have a flat portion parallel to the upper surface of the substrate.

16. The angular velocity sensor of claim 13, wherein the side surface of the piezoelectric body has a flat portion parallel to the upper surface of the substrate.

17. The angular velocity sensor of claim 1, wherein the supplementary angle is larger than 20°.
